(19) United States
(12) Patent Application Publication
(10) Pub. No.: US 2008/0024997 A1
(43) Pub. Date: Jan. 31, 2008

(54) STAGGERED MEMORY LAYOUT FOR IMPROVED COOLING IN REDUCED HEIGHT ENCLOSURE

(75) Inventor: Nayana Ghantiwala, San Jose, CA (US)

Correspondence Address: GAZDZINSKI & ASSOCIATES, P.C., 11440 WEST BERNARDO COURT, SUITE 375, SAN DIEGO, CA, 92127, US

(73) Assignee: APPLE COMPUTER, INC., Cupertino, CA (US)

(21) Appl. No.: 11/460,779

(22) Filed: Jul. 28, 2006

(51) Int. Cl. H05K 7/20; F28F 13/12; H01L 23/34

(52) U.S. Cl. 361/719; 165/109.1; 257/722

(57) ABSTRACT

A plurality of memory lies within the airflow created by the cooling fans and includes modules arranged in a plurality of pairs of memory modules aligned in substantially the same direction as airflow. Each pair has a first memory module and a second memory module, the first and second memory modules each have a length, and the first memory module and the second module are disposed such that the length of the first memory module is in a substantially parallel relationship with respect to the length of the second memory module. A portion of the length of the first memory module is disposed between another pair of memory modules.

### FIELD

The present invention relates broadly to circuit board design. Specifically, the present invention relates to removing heat from components on a circuit board. More specifically, the present invention relates to arranging memory modules to allow improved cooling on the circuit board.

### BACKGROUND

Heat is a traditional enemy of circuit board designers in the computer industry. Excessive heat causes components to fail or, at the very least, operate in error. Because heat is such a problem, very clear design rules are followed that minimize the effect heat has on various components on a circuit board. The problem is somewhat more significant when larger geometries are involved, such as found in computers that have multiple central processing units, chipsets, power supply units, memories, and storage devices. Cooling equipment such as heat sinks and fans are used in various configurations to remove heat from the various components, and components may incorporate power saving modes that allow less power to be used (and therefore less heat to be generated) when the component is not being used. Power distribution is always a prime consideration for managing heat within circuit board design. The particular board layout is constrained by distribution of power resulting in heat generation and the efficiency of cooling systems that can be applied in a given board layout. Placement of the components and cooling applications is often dictated by a heat budget that designers adhere to in order to keep components from failing or operating in error.

Coupled with the problem of heat is the design goal of accommodating more data and accessing it at a faster rate. Memory is often arranged in a grouping or collection of memory modules. Technological advances in memories are of particular concern to board designers. Currently, a popular choice among board designers is the single inline memory module (SIMM), a small circuit board that contains memory chips served by a 32-bit path. Pentium processors from Intel are often used in circuit board design, and require a 64-bit path to memory mandate that SIMMs are installed two at a time. Because they are installed in pairs, it is common to place fans proximate to rows of SIMMs and blow cooler air down the channels defined by the placement of the SIMMs, which absorbs heat from the SIMMs as it passes them. For example, as shown in FIG. 1, within multiple rows of memory, row of memory 10 and row of memory 12 define channel 14 in which heat from memory 10, 12 is removed by the placement of fans 16. However, these rows of memory have to be separated by minimum distances for effective cooling. Because area on the circuit board is a precious commodity in board design, there is a heart-felt need for a memory layout and cooling mechanism that consumes less area on a circuit board than required by current minimum distances.

### SUMMARY

In one aspect, the present invention provides a printed circuit board that has a plurality of cooling fans and a plurality of memory modules. The cooling fans are arranged to blow air in substantially the same direction. The plurality of memory lies within the airflow created by the cooling fans and includes modules arranged in a plurality of pairs of memory modules aligned in substantially the same direction as airflow. Each pair has a first memory module and a second memory module, the first and second memory modules each have a length, and the first memory module and the second module are disposed such that the length of the first memory module is in a substantially parallel relationship with respect to the length of the second memory module. A portion of the length of the first memory module is disposed between another pair of memory modules arranged in a substantially parallel relationship with respect to each other, wherein the plurality of memory modules is disposed such that airflow is directed along the length of the memory modules between opposing memory modules.

In another aspect, the present invention provides a low profile server computer, preferably sized to a 1 U chassis. The computer has a storage array, an array of cooling fans; and a plurality of dual inline memory modules. The array of fans separates the storage array from the plurality of dual in line memory modules. The storage array is positioned proximate to the array of cooling fans, which are configured in an alignment to draw air from the storage array and direct the drawn air to channels defined by a plurality of memory modules. The memory modules are aligned in the direction of the flow of the drawn air along the channels. The memory modules are partially interleaved with neighboring memory modules. The interleaved memory modules having partial overlap with at least one neighboring memory module, such that a channel separates the partially interleaved memory modules from all neighboring memory modules.

In yet another aspect, the present invention provides a method of cooling components on a printed circuit board, by activating a plurality of fans configured to blow air in the same direction across a plurality of memory modules disposed in a substantially parallel relationship with respect to each other and arranged in a staggered relationship, wherein each memory module is positioned partially opposite at least one neighboring memory module, with the neighboring memory module in a substantially parallel orientation with respect to the memory module of the plurality. The orientation defines, for each contiguous memory module pair, a channel between the memory module of the plurality and the neighboring memory module(s), the channel aligned with the direction of air flow through which air is moved by a portion of the fans in the plurality.

When dual inline memory modules are used in accordance with the present invention, they can be located at a minimum distance of 10.16 millimeters from the closest neighboring memory module.

Many additional features and advantages of the present invention will become apparent after reading the following detailed description, when considered in conjunction with the drawings, in which:

### BRIEF DESCRIPTION OF THE DRAWINGS

FIG. 1 is a plan view of memory modules and cooling fans as used in existing architectures.

FIG. 2 is a plan view of a printed circuit board utilizing memory modules and cooling fans in accordance with an embodiment of the present invention.

FIG. 3 is a plan view of memory modules arranged in accordance with the present invention.

FIG. 4 is a perspective view of memory modules arranged in accordance with the present invention.

### DETAILED DESCRIPTION

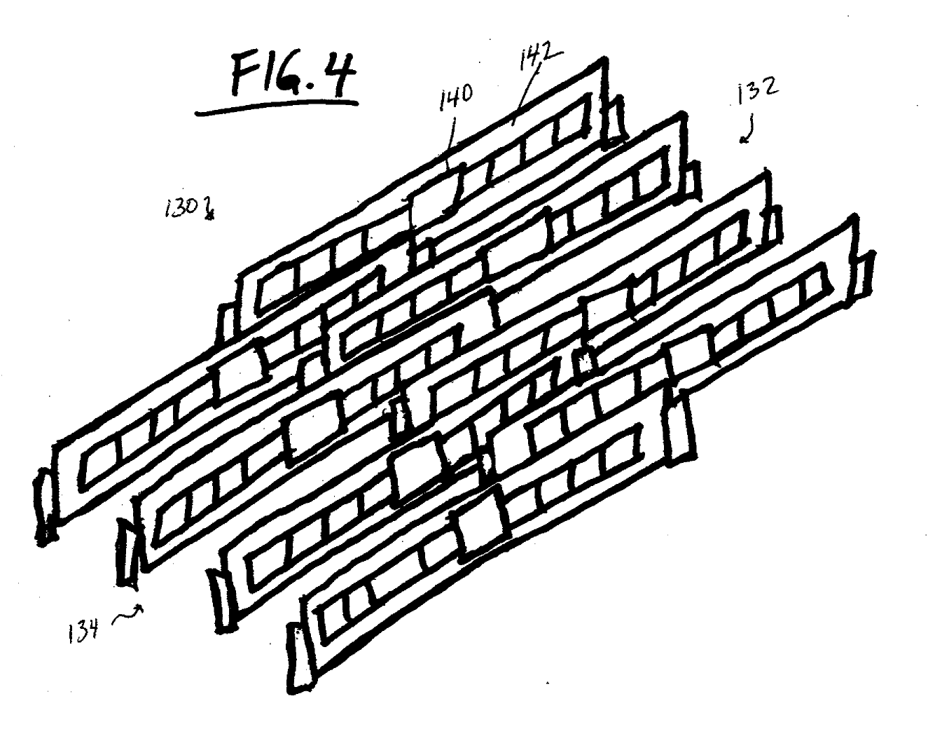

Directing attention to FIG. 3, there is shown generally a computer server having a plurality of components. In an embodiment, computer 100 is a low-profile, rack-mounted server. Computer 100 includes cooling fans 102, which serve to draw heat from a pair of redundant power supply units 104. Power supply units 104 power the various components located on main logic board (MLB) 106 and elsewhere on computer 100. Power is distributed to the components by power distribution board 108. Chipset 110 includes Southbridge 112 and Northbridge 114, shown in an embodiment oriented proximate to central processing units (CPUs) 116. In the preferred embodiment CPUs 116 in the preferred embodiment are Pentium™ processors available from Intel Corporation. Communication is handled by input/output connectors 118 located on the back panel of computer 100, as well as peripheral connect interface (PCI) cards (not shown), and graphics processing unit (GPU) 122. In the preferred embodiment, the PCI cards are nine inches and 6.5 inches long. Storage on computer 100 includes three hard disk drives 124 connected to hard disk drive backplane board 125. Storage also includes CD/DVD Superdrive 126. LED board 128 is located near the front panel of computer 100 to provide information to a user, and chassis stiffener 129 is located above hard disk drives 124.

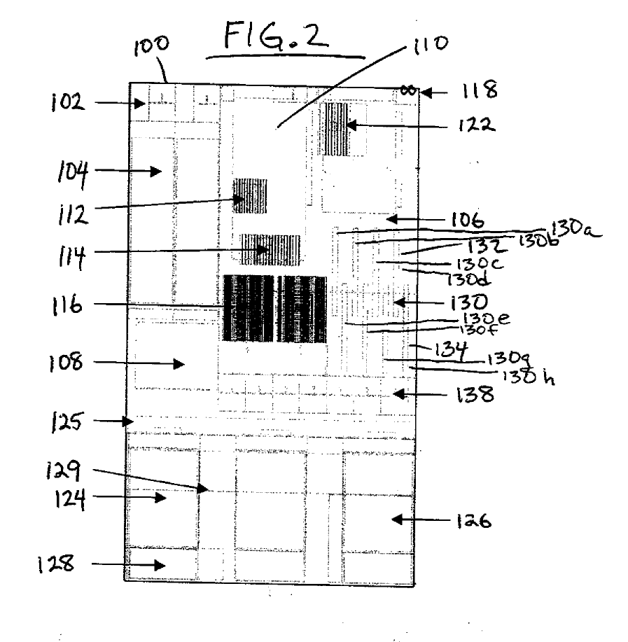

Also proximate to CPUs 116 are memory modules 130. Memory modules 130, in an embodiment, utilize dual inline memory modules (DIMMs) that are similar to SIMMs but have a 64-bit path to the memory chips contained within each individual DIMM. As this 64-path is compatible with the Pentium™ family of processors, DIMMs can be installed one DIMM at a time, rather than in pairs as SIMMs require. DIMMs also can be placed closer together than SIMMs can, making them easier to configure with respect to cooling fans. Normally, DIMMs are spaced at a pitch of 10-12 mm, limited primarily by socket dimensions. A staggered layout has a significant advantage of increased airflow, since the channel for air is widened to 27 mm. FB-DIMMs have extremely high power (15 W) and need an air velocity of greater than 2.5 meter per second to perform in 40 degrees Celsius ambient temperature. This is important for a 1 U server enclosure having a minimal height. As shown in FIGS. 2 and 3, memory modules 130 are organized into two groups. Group 132 includes memory modules 130a-130d, and group 134 includes memory modules 130e-130h. Each row of memory modules 130 within groups 132, 134 defines, with its neighboring row, channel 136 through which air from fans 138 passes, removing heat from memory modules 130.

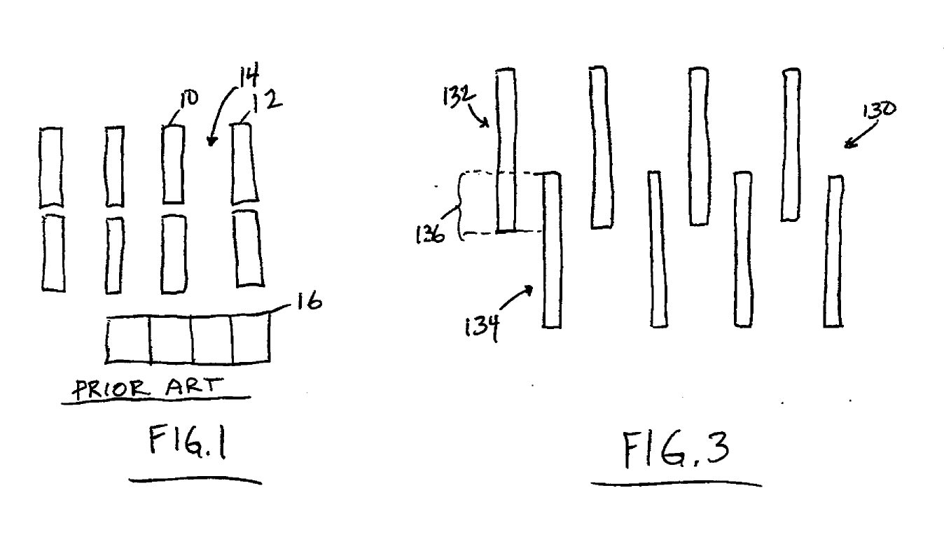

As shown in FIG. 3, memory modules 130 are disposed such that memory module groups 132, 134 are interleaved with respect to each other. This decreases the area of the circuit board required to accommodate memory modules 130, and frees it for other uses or components. As shown, overlapping area 136 allows memory modules to be concentrated in a smaller area than required for memory modules 10, 12 in FIG. 1. The amount of overlap can be varied, depending on power budgets. Also, it is to be understood that groups 132, 134 do not necessarily require memory modules to be perfectly aligned within groups 132, 134.

As shown in FIG. 4, memory modules 130 in the preferred embodiment utilize advanced memory buffer 140. As memory buffer 140 radiates heat, in the preferred embodiment, heat sink 142 is bonded or secured to the surface of memory buffer 140 to absorb heat. Heat spreaders may also be used with memory modules 130.

A staggered memory layout for improved cooling in reduced height enclosure has been described and illustrated in detail, it is to be understood that numerous changes and modifications can be made to various embodiments of the present invention without departing from the spirit thereof.

What is claimed is:

1. A printed circuit board comprising:
a plurality of cooling fans and a plurality of memory modules, the plurality of cooling fans arranged to blow air in substantially the same direction, the plurality of memory modules arranged in substantially the same direction as airflow created by the plurality of fans, the plurality of memory modules comprising a first memory module and a second memory module, the first and second memory modules each having a length, wherein the first memory module and the second module are disposed such that the length of the first memory module is in a substantially parallel relationship with respect to the length of the second memory module, and a third memory module having a length, the third memory module aligned in substantially a parallel relationship with respect to the first and second memory modules, such that a portion of the length of the third memory module is disposed between the first and second memory modules.

2. The printed circuit board of claim 1, wherein the memory module comprises a dual inline memory module configured with an advanced memory buffer chip.

3. The printed circuit board of claim 2, wherein the memory module comprises a heatsink in contact with the advanced memory buffer chip.

4. The printed circuit board of claim 1, wherein air gaps of two millimeters separate the memory modules.

5. The printed circuit board of claim 1, further comprising at least one processor located adjacent to the plurality of dual inline memory modules, the at least one processor located within a portion of airflow created by the array of cooling fans.

6. The printed circuit board of claim 1, further comprising a plurality of storage modules, the plurality of cooling fans disposed between the memory modules and the storage modules.

7. A circuit board comprising:
a plurality of cooling fans and a plurality of dual inline memory modules, the plurality of cooling fans arranged to blow air in substantially the same direction; and
a plurality of dual inline memory modules, the plurality of dual inline memory modules arranged in a plurality of pairs of memory modules aligned in the same direction as airflow created by the plurality of fans, each pair having a first memory module and a second memory module, the first and second memory modules each having a length, wherein the first memory module and the second module are disposed such that the length of the first memory module is in a substantially parallel relationship with respect to the length of the second memory module, wherein a portion of the length of the first memory module is disposed between another pair of memory modules arranged in a substantially parallel relationship with respect to each other, wherein the plurality of dual inline memory modules is disposed such that airflow is directed along the length of the memory modules between opposing memory modules.

8. The printed circuit board of claim 6, wherein the memory module comprises a dual inline memory module configured with an advanced memory buffer chip.

9. The printed circuit board of claim 7, wherein the memory module comprises a heatsink in contact with the advanced memory buffer chip.

10. The printed circuit board of claim 6, wherein air gaps of two millimeters separate the memory modules.

11. The printed circuit board of claim 6, further comprising at least one processor located adjacent to the plurality of dual inline memory modules, the at least one processor located within a portion of airflow created by the array of cooling fans.

12. The printed circuit board of claim 1, further comprising a plurality of storage modules, the plurality of cooling fans disposed between the memory modules and the storage modules.

13. A low profile server computer, comprising:
a storage array;
an array of fans; and
a plurality of dual inline memory modules, the array of fans separating the location of the storage array from the location of the plurality of dual in line memory modules, the storage array positioned proximate to an array of cooling fans, the cooling fans configured in an alignment to draw air from the storage array and direct the drawn air to channels defined by a plurality of memory modules, the memory modules aligned in the direction of the flow of the drawn air to form channels, comprising dual inline memory modules partially interleaved with neighboring memory modules, the partially interleaved memory modules having partial overlap with at least one neighboring memory module the partial overlapping area not exceeding one inch in width, such that a channel separates the partially interleaved memory modules from all neighboring memory modules.

14. The computer of claim 13, wherein the memory module comprises a dual inline memory module configured with an advanced memory buffer chip.

15. The computer of claim 14, wherein the memory module comprises a heatsink in contact with the advanced memory buffer chip.

16. The computer of claim 13, wherein air gaps of two millimeters separate the memory modules.

17. The computer of claim 13, wherein the partial overlapping area of the memory module does not exceeding one inch in width.

18. The computer of claim 13, further comprising at least one processor located adjacent to the plurality of dual inline memory modules, the at least one processor located within a portion of airflow created by the array of cooling fans.

19. The computer of claim 13, further comprising a plurality of storage modules, the plurality of cooling fans disposed between the memory modules and the storage modules.

20. The computer of claim 13, wherein the computer fits in a 1 U chassis.

21. A method of cooling components on a printed circuit board, comprising:
activating a plurality of fans configured to blow air in the same direction across a plurality of memory modules, the memory modules arranged in a staggered relationship, wherein each memory module is positioned partially opposite at least one neighboring memory module, the at least one neighboring memory module in a substantially parallel orientation with respect to said memory module of the plurality, said orientation defining, for each contiguous memory module pair, a channel between the memory module of the plurality and the at least one neighboring memory module, the channel aligned with the direction of air flow through which air is moved by a portion of the fans in the plurality.

22. The method of claim 21, wherein the memory modules comprise dual inline memory modules incorporating an advanced memory buffer chip in contact with a heat sink.

23. A method of cooling components in a low profile server computer configuration, the method comprising:
operating a plurality of cooling fans simultaneously, such that air in an area of sufficient width to accompany at least one processor and a memory array, the memory array comprising partially interleaved memory modules, the partially interleaved memory modules having partial overlap with at least one neighboring memory module, the partial overlap not exceeding one inch in width, such that a minimum distance of two millimeters separates the partially interleaved memory modules from all neighboring memory modules.

24. The method of claim 23, wherein the memory modules comprise dual inline memory modules incorporating an advanced memory buffer chip in contact with a heat sink.

25. A method of cooling components in a low profile server computer configuration, the method comprising:
moving air from an area surrounding storage components to air channels located between interleaved memory modules, the partially interleaved memory modules having partial overlap with at least one neighboring memory module the partial overlapping area not exceeding one inch in width, such that a minimum distance of two millimeters separates the partially interleaved memory modules from all neighboring memory modules.

26. The method of claim 25, wherein the memory modules comprise dual inline memory modules incorporating an advanced memory buffer chip in contact with a heat sink.
